(19) United States
(12) Patent Application Publication
(10) Pub. No.: US 2021/0083016 A1
(43) Pub. Date: Mar. 18, 2021

(54) DISPLAY DEVICE, DISPLAY DEVICE MANUFACTURING METHOD, AND DISPLAY DEVICE MANUFACTURING APPARATUS

(71) Applicant: Sharp Kabushiki Kaisha, Sakai City, Osaka (JP)

(72) Inventor: Koji YAMABUCHI, Sakai City (JP)

(21) Appl. No.: 16/620,070

(22) PCT Filed: Jun. 13, 2017
(86) PCT No.: PCT/JP2017/021776

§ 371 Date: Dec. 6, 2019

(51) Int. Cl. H01L 27/32; H01L 51/56

(52) U.S. Cl. CPC H01L 27/3218; H01L 51/56

(57) ABSTRACT

A first subpixel, a second subpixel, a third subpixel, a fourth subpixel, and a fifth subpixel are included. The first subpixel and the fourth subpixel adjacent to each other in a first direction share an island-shaped light-emitting layer configured to emit light of a first color. The third subpixel and the fifth subpixel adjacent to each other in the first direction share an island-shaped light-emitting layer configured to emit light of a second color. The first subpixel and the third subpixel are adjacent to each other in a second direction orthogonal to the first direction.

### TECHNICAL FIELD

The disclosure relates to a display device.

### BACKGROUND ART

PTL 1 discloses a configuration in which a light-emitting layer common to a plurality of subpixels of the same color is provided in an organic EL display.

### CITATION LIST

### Patent Literature

PTL 1: JP 2011-48962 A (published on Mar. 10, 2011)

### SUMMARY

### Technical Problem

In PTL 1, a mask used to form the light-emitting layer is a stripe type (slit type), and this type has a property that the slit position is likely to be shifted. Accordingly, there is a problem in that it is difficult to achieve a high resolution and a large size.

### Solution to Problem

A display device according to an aspect of the disclosure includes a first subpixel, a second subpixel, a third subpixel, a fourth subpixel, and a fifth subpixel. The first subpixel and the fourth subpixel adjacent to each other in a first direction share an island-shaped light-emitting layer configured to emit light of a first color, the third subpixel and the fifth subpixel adjacent to each other in the first direction share an island-shaped light-emitting layer configured to emit light of a second color, and the first subpixel and the third subpixel are adjacent to each other in a second direction orthogonal to the first direction.

### Advantageous Effects of Disclosure

According to the aspect of the disclosure, it is possible to cause a resolution of an opening of a mask used to form a light-emitting layer of each of colors to be lower than a resolution of a subpixel of each of the colors. Therefore, the aspect of the disclosure is suitable for achieving a high resolution and a large size.

### BRIEF DESCRIPTION OF DRAWINGS

FIG. 1 is a flowchart illustrating an example of a manufacturing method for a display device.

FIG. 2 is a cross-sectional view illustrating a configuration example of a display device.

FIG. 3 is a plan view illustrating a subpixel structure according to a first embodiment.

FIG. 4(a) is a plan view illustrating the subpixel structure according to the first embodiment, FIG. 4(b) is a plan view illustrating a configuration of a mask (for red subpixels) used in the first embodiment, FIG. 4(c) is a plan view illustrating a configuration of a mask (for blue subpixels) used in the first embodiment, FIG. 4(d) is a plan view illustrating a configuration of a mask (for green subpixels) used in the first embodiment, FIG. 4(e) is a cross-sectional view illustrating a configuration of adjacent red subpixels, and FIG. 4(f) is a cross-sectional view illustrating a configuration of adjacent blue subpixels.

FIG. 5 is a cross-sectional view illustrating a vapor deposition method for a light-emitting layer (red) according to the first embodiment.

FIG. 6 is a block diagram illustrating a configuration of a display device manufacturing apparatus according to the first embodiment.

FIG. 7(a) is a plan view illustrating a subpixel structure of a reference example, FIG. 7(b) is a plan view illustrating a configuration of a mask (for red subpixels) used in the reference example, FIG. 7(c) is a plan view illustrating a configuration of a mask (for blue subpixels) used in the reference example, and FIG. 7(d) is a plan view illustrating a configuration of a mask (for green subpixels) used in the reference example.

FIG. 8 is a plan view illustrating modification examples of subpixel arrangement according to the first embodiment.

FIG. 9 is a plan view illustrating subpixel arrangement according to a second embodiment.

FIG. 10 is a plan view illustrating a modification example of the subpixel arrangement according to the second embodiment.

FIG. 11 is a plan view illustrating a modification example of FIG. 10.

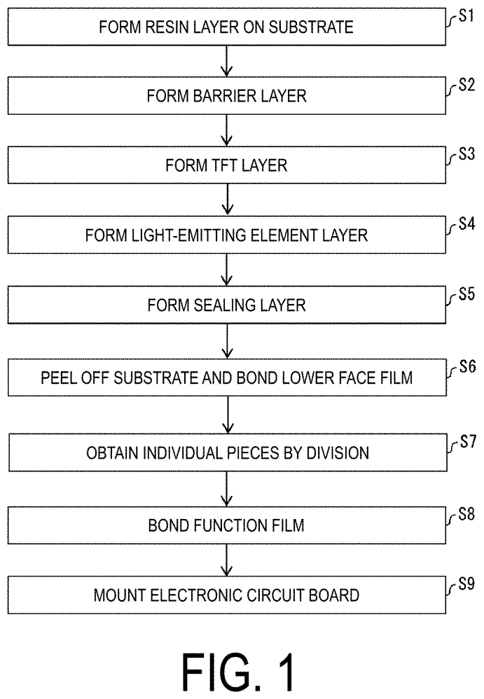

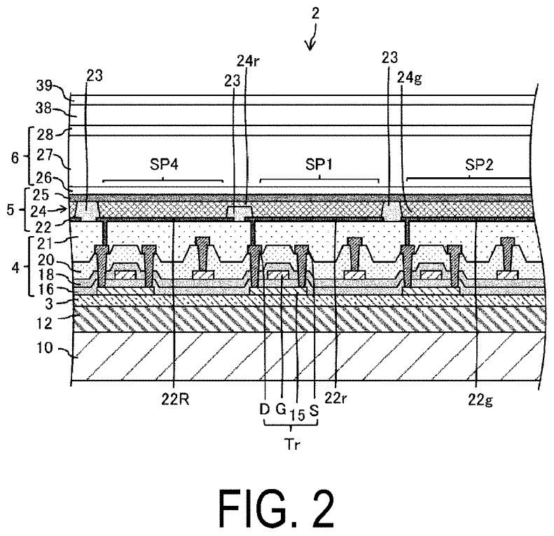

FIG. 1 is a flowchart illustrating an example of a manufacturing method for a display device. FIG. 2 is a cross-sectional view illustrating a configuration example of a display device. For example, in a case of manufacturing a flexible display device, a resin layer 12 is first formed on a substrate (for example, mother glass) as illustrated in FIG. 1 and FIG. 2 (step S1). Next, an inorganic barrier film 3 is formed (step S2). Next, a TFT layer 4 is formed (step S3). Next, a light-emitting element layer (for example, an OLED element layer) 5 is formed (step S4). Next, a sealing layer 6 is formed (step S5). Next, the substrate (for example, mother glass) is peeled off by laser irradiation, and a lower face film 10 is bonded (step S6). Next, partitioning is performed to cut out a plurality of individual pieces (step S7). Next, a function film 39 is bonded onto the upper side of the sealing layer 6 of the individual piece, with an adhesive layer 38 interposed therebetween (step S8). Next, an electronic circuit board (an IC chip, a flexible printed circuit (FPC), or the like) is mounted on a terminal portion of the individual piece (step S9). In this way, a display device 2 illustrated in FIG. 2 is obtained. Note that each of the steps illustrated in FIG. 1 is performed by a display device manufacturing apparatus. In a case of manufacturing an inflexible display device, it is possible to skip step S6.

The lower face film 10 is formed of PET or the like, and functions as a support member and a protection member. Examples of the material used in the resin layer 12 include polyimide, epoxy, and polyamide. Examples of the material used in the lower face film 10 include polyethylene terephthalate (PET).

The barrier layer 3 is a layer that inhibits moisture or impurities from reaching the TFT layer 4 or the light-emitting element layer 5 when the display device is being used, and may be constituted by a silicon oxide film, a silicon nitride film or a silicon oxynitride film, or by a layered film of these, formed using chemical vapor deposition (CVD), for example.

The TFT layer 4 includes a semiconductor film 15, an inorganic insulating film 16 (a gate insulating film) formed on the semiconductor film 15, a gate electrode G formed on the inorganic insulating film 16, an inorganic insulating film 18 formed on the gate electrode G, a capacitance wiring line C formed on the inorganic insulating film 18, an inorganic insulating film 20 formed on the capacitance wiring line C, a source electrode S and a drain electrode D formed on the inorganic insulating film 20, and a flattening film 21 formed on the source electrode S and the drain electrode D.

A thin film transistor Tr is configured to include the semiconductor film 15, the inorganic insulating film 16 (the gate insulating film), and the gate electrode G. The source electrode S is connected to a source region of the semiconductor film 15, and the drain electrode D is connected to a drain region of the semiconductor film 15.

The semiconductor film 15 is formed of low-temperature polysilicon (LTPS) or an oxide semiconductor, for example. The gate insulating film 16 may be configured by a silicon oxide (SiOx) film, a silicon nitride (SiNx) film, or a layered film thereof formed using a CVD method, for example. The gate electrode G, the source wiring line S, and the drain wiring line D are each constituted by a single-layer metal film or a layered metal film including at least one of aluminum (Al), tungsten (W), molybdenum (Mo), tantalum (Ta), chromium (Cr), titanium (Ti), and copper (Cu), for example. Note that, although the TFT provided with the semiconductor film 15 as the channel is illustrated as having a top gate structure in FIG. 2, the TFT may have a bottom gate structure (when the TFT channel is an oxide semiconductor, for example).

The inorganic insulating films 18 and 20 may be constituted by a silicon oxide (SiOx) film or a silicon nitride (SiNx) film, or a layered film of these, formed using the CVD method. The flattening film (interlayer insulating film) 21 may be constituted, for example, by a coatable photosensitive organic material, such as a polyimide or an acrylic.

The light-emitting element layer 5 (for example, an organic light emitting diode layer) includes anodes (first electrodes) 22r, 22R, and 22g formed on the flattening film 21, a bank (partition) 23 that defines subpixels, an electroluminescence (EL) layer 24 formed on the anodes, and a cathode (a second electrode) 25 formed on the EL layer 24. In a case that the light-emitting element layer 5 is an organic light emitting diode (OLED) layer, it may be formed by layering a hole injection layer, a hole transport layer, a light-emitting layer, an electron transport layer, and an electron injection layer from a lower layer side by vapor deposition, for example. Note that only a light-emitting layer is described in the EL layer 24 in FIG. 2 and the like. The light-emitting layer is formed in an island shape, but at least one layer among the hole injection layer, the hole transport layer, the light-emitting layer, the electron transport layer, and the electron injection layer may be formed as a solid-like common layer. For example, the light-emitting layers (R, G, B) and the hole transport layers (G, R) may be formed in island shapes, and the other layers may be formed as common layers. Such a configuration is also possible that at least one layer among the hole injection layer, the hole transport layer, the electron transport layer, and the electron injection layer is not formed.

A light emitting element (for example, an organic light emitting diode (OLED)) is configured by the electrically independent anodes (22r, 22R, 22g), the EL layer 24, and the cathode 25. Edges of each anode are covered with the banks 23, and a subpixel is configured by a region within the banks of each anode (an exposed region being not covered with the banks), and the EL layer (including the light-emitting layer) and the cathode overlapping with the above region. A region of the light-emitting layer overlapping with the exposed region of each anode (the region not covered with the banks) is a light emitting region. In order to drive the subpixels, a subpixel circuit is provided for each subpixel in the TFT layer 4.

In FIG. 2, a red subpixel SP1 includes the anode 22r, a red subpixel SP4 includes the anode 22R, and the red subpixels SP1 and SP4 share an island-shaped light-emitting layer 24r that emits red light. A green subpixel SP2 includes the anode 22g and a light-emitting layer 24g that emits green light, and the subpixels SP1, SP2, and SP4 include the common cathode 25. For example, the island-shaped light-emitting layer 24r is formed to straddle the bank 23 separating the subpixel SP1 and the subpixel SP4 from each other. The red subpixels SP1 and SP4 share one island-shaped light-emitting layer 24r, but each anode thereof is electrically independent so that the brightness of each of the subpixels SP1 and SP4 is separately controlled.

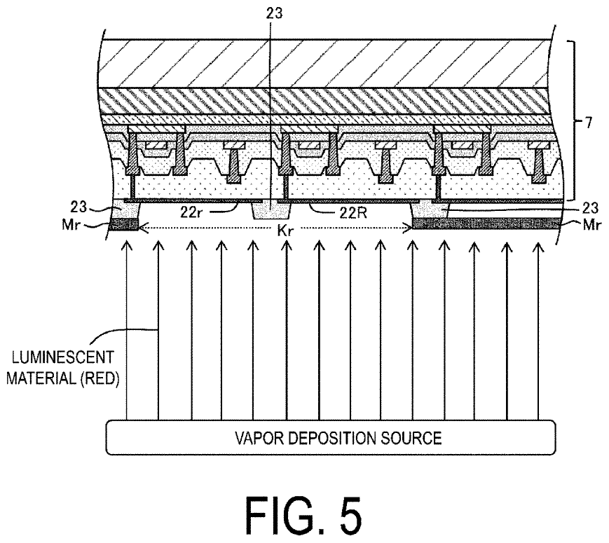

In FIG. 2, the bank 23 separating the subpixels SP1 and SP4 is lower in height than the bank 23 separating the subpixels SP1 and SP2 for the sake of convenience in description, and therefore both of them may have the same height (see FIG. 5). However, it is also possible to make the former (the bank 23 separating the subpixels SP1 and SP4) higher than the latter (the bank 23 separating the subpixels SP1 and SP2), or to make the latter higher than the former. A protruding portion formed by a higher bank may be made to be an abutment portion of the mask during vapor deposition.

The anodes (22r, 22R, 22g) are formed by, for example, the layering of indium tin oxide (ITO) and an alloy containing Ag, and have light reflectivity. The cathode 25 may be constituted by a transparent conductive material such as indium tin oxide (ITO) or indium zincum oxide (IZO).

When the light-emitting element layer 5 is an OLED layer, a positive hole and an electron are recombined in the EL layer 24 due to the drive current between the anodes (22r, 22R, 22g) and the cathode 25, and an exciton generated by the recombination falls to a ground state, thereby releasing light. Since the cathode 25 is transparent and the anode 22 has light reflectivity, the light released from the light-emitting layer of the EL layer 24 travels upward to be top-emitting.

The light-emitting element layer 5 may be used not only in a case of constituting the OLED element, but also in a case of constituting an inorganic light emitting diode or a quantum dot light emitting diode.

The sealing layer 6 is transparent, and includes a first inorganic sealing film 26 that covers the cathode 25, an organic sealing film 27 that is formed on the first inorganic sealing film 26, and a second inorganic sealing film 28 that covers the organic sealing film 27.

Each of the first inorganic sealing film 26 and the second inorganic sealing film 28 may be made of, for example, a silicon oxide film, a silicon nitride film or a silicon oxynitride film, or a layered film thereof, formed by CVD using a mask.

The organic sealing film 27 is thicker than the first inorganic sealing film 26 and the second inorganic sealing film 28, is a transparent organic film, and may be constituted by a coatable photosensitive organic material such as a polyimide or an acrylic. For example, after the first inorganic sealing film 26 is coated, by an ink-jet method, with an ink containing such an organic material, the ink is cured by ultraviolet (UV) irradiation. The sealing layer 6 covers the light-emitting element layer 5 and inhibits foreign matters, such as water and oxygen, from infiltrating into the light-emitting element layer 5.

The function film 39 has an optical compensation function, a touch sensor function, and a protection function, for example.

### First Embodiment

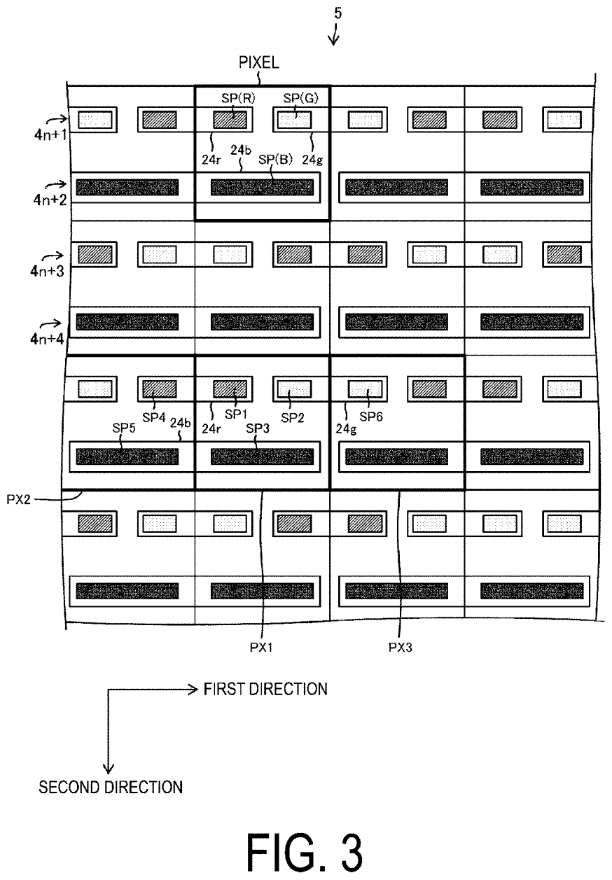

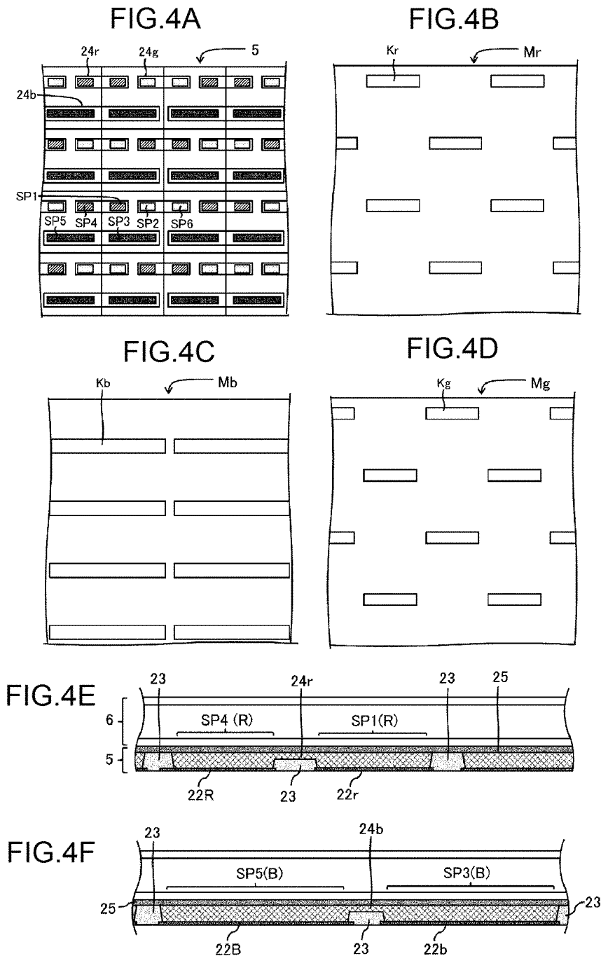

FIG. 3 is a plan view illustrating a subpixel structure according to a first embodiment. FIG. 4(a) is a plan view illustrating the subpixel structure according to the first embodiment, FIG. 4(b) is a plan view illustrating a configuration of a mask (for red subpixels) used in the first embodiment, FIG. 4(c) is a plan view illustrating a configuration of a mask (for blue subpixels) used in the first embodiment, FIG. 4(d) is a plan view illustrating a configuration of a mask (for green subpixels) used in the first embodiment, FIG. 4(e) is a cross-sectional view illustrating a configuration of adjacent red subpixels, and FIG. 4(f) is a cross-sectional view illustrating a configuration of adjacent blue subpixels.

As illustrated in FIG. 3, the display device 2 includes a plurality of pixels PX arranged in a first direction (lateral direction in the drawing) and a second direction (longitudinal direction in the drawing). The pixel PX is configured by a red subpixel SP(R), a blue subpixel SP(B), and a green subpixel SP(G); the subpixel SP(R) and subpixel SP(G) are adjacent to each other in the first direction, and the subpixel SP(B) having a shape extended in the first direction is adjacent to each of the red subpixel SP(R) and the subpixel SP(G) in the second direction; in this manner, each subpixel constitutes an OLED.

In the display device 2 according to the first embodiment, the first direction is a row direction, and the second direction is a column direction; n is an integer equal to or greater than 0; in the (4n+1)th and (4n+3)th subpixel rows, a red subpixel pair formed of two red subpixels adjacent in the first direction and a green subpixel pair formed of two green subpixels adjacent in the first direction are alternately arranged; in the (4n+2)th and (4n+4)th rows, a blue subpixel pair formed of two blue subpixels adjacent in the first direction is arranged side by side. In each pair, the two subpixels adjacent in the first direction share a light-emitting layer. When viewed in the second direction, alignment of a red subpixel, blue subpixel, green subpixel, and blue subpixel, or alignment of a green subpixel, blue subpixel, red subpixel, and blue subpixel is repeated.

The display device 2 is provided with a first subpixel SP1 (red), a second subpixel SP2 (green), a third subpixel SP3 (blue), a fourth subpixel SP4 (red), a fifth subpixel SP5 (blue), and a sixth subpixel SP6 (green). The first subpixel SP1 and the second subpixel SP2 are adjacent to each other in the first direction, and the third subpixel SP3 is adjacent to the first subpixel SP1 and the second subpixel SP2 in the second direction; the pixel PX1 is configured by the first subpixel SP1, the second subpixel, and the third subpixel SP3; one of the two pixels adjacent to the pixel PX1 in the first direction (PX2) includes the fourth subpixel SP4 and the fifth subpixel SP5, and the other one thereof (PX3) includes the sixth subpixel SP6.

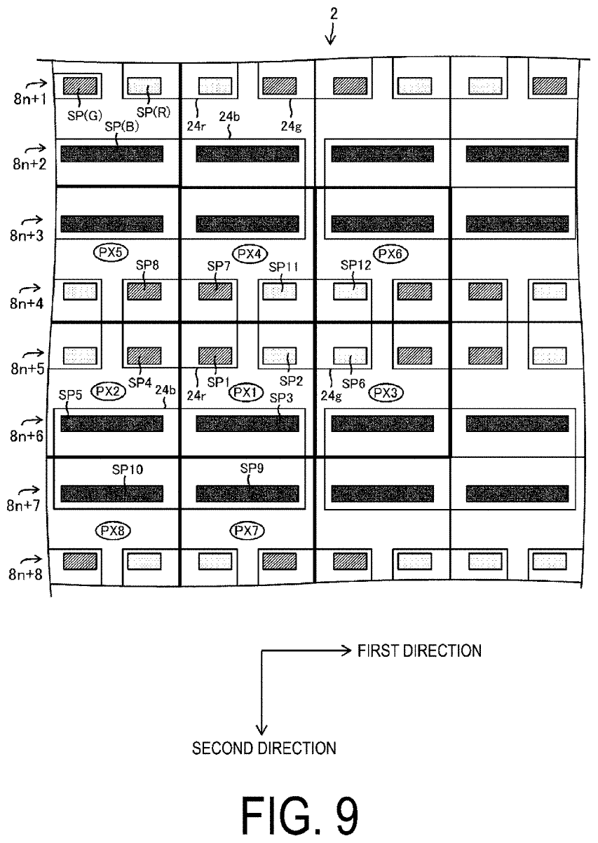

In FIG. 9, as for two pixels adjacent in the first direction (for example, PX1 and PX2), the arrangement of three subpixels (red, blue, green) in the respective pixels is line-symmetric while taking a boundary line extending in the second direction between subpixels on both sides as the axis of symmetry. The first subpixel SP1 and the fourth subpixel SP4 adjacent in the first direction share an island-shaped light-emitting layer 24r that emits red light, and the third subpixel SP3 and the fifth subpixel SP5 adjacent in the first direction share an island-shaped light-emitting layer 24b that emits blue light; the first subpixel SP1 and the third subpixel SP3 are adjacent to each other in the second direction orthogonal to the first direction; the second subpixel SP2 and the sixth subpixel SP6 adjacent in the first direction share an island-shaped light-emitting layer 24g that emits green light.

Each of the first subpixel SP1 to the sixth subpixel SP6 has an electrically independent anode. For example, as illustrated in FIGS. 4(e) and 4(f), the first subpixel SP1 includes an anode 22r, the fourth subpixel SP4 includes an anode 22R, the third subpixel SP3 includes an anode 22b, and the fifth subpixel SP5 includes an anode 22B. In addition, the first subpixel SP1 to the sixth subpixel SP6 include a common cathode 25.

The display device 2 is provided with subpixel circuits on a subpixel-by-subpixel basis, and a potential of the anode of each subpixel is set by the subpixel circuit formed in the TFT layer 4, whereby a current corresponding to a data signal flows in each subpixel (OLED).

The third subpixel SP3 (blue) has a larger light emitting region than the first subpixel SP1 (red) and the second subpixel SP2 (green). Specifically, the size in the first direction of the light emitting region is larger. Although, in general, a blue light-emitting layer is more likely to be degraded than a red light-emitting layer and a green light-emitting layer, it possible to compensate for the degradation of the blue light by employing the above-mentioned configuration.

The island-shaped light-emitting layer 24b (blue) shared by the third subpixel SP3 and the fifth subpixel SP5 is larger in area than the island-shaped light-emitting layer 24r (red) shared by the first subpixel SP1 and fourth subpixel SP4, and than the island-shaped light-emitting layer 24g (green) shared by the second subpixel SP2 and sixth subpixel SP6.

Step S4 in FIG. 1 includes a red light-emitting layer formation process in which the island-shaped light-emitting layer 24r shared by the first subpixel SP1 and the fourth subpixel SP4 is formed, a blue light-emitting layer formation process in which the island-shaped light-emitting layer 24b shared by the third subpixel SP3 and the fifth subpixel SP5 is formed, and a green light-emitting layer formation process in which the island-shaped light-emitting layer 24g shared by the second subpixel SP2 and the sixth subpixel SP6 is formed.

For example, in the red light-emitting layer formation process, as illustrated in FIG. 5, a mask Mr is positioned to be aligned with a layered body 7 in which a substrate, a resin layer, a barrier layer, a TFT layer, anodes 22r and 22R, and banks 23 are layered, and a red luminescent material from a vapor deposition source is allowed to pass through an opening Kr overlapping with the anodes 22r and 22R to be deposited in the inner side of the banks 23.

As illustrated in FIGS. 4(b), 4(c), and 4(d), a resolution of the opening Kr in the mask Mr used in the red light-emitting layer formation process is lower than that of the red subpixels (SP1, SP4, and the like), a resolution of an opening Kb in a mask Mb used in the blue light-emitting layer formation process is lower than that of the blue subpixels (SP3, SP5, and the like), and a resolution of an opening Kg in a mask Mg used in the green light-emitting layer formation process is lower than that of the green subpixels (SP2, SP6, and the like).

The opening Kb in the mask Mb is larger than the opening Kr in the mask Mr and the opening Kg in the mask Mg. The resolution (the number of openings) of each of the masks Mr, Mb, and Mg is the same.

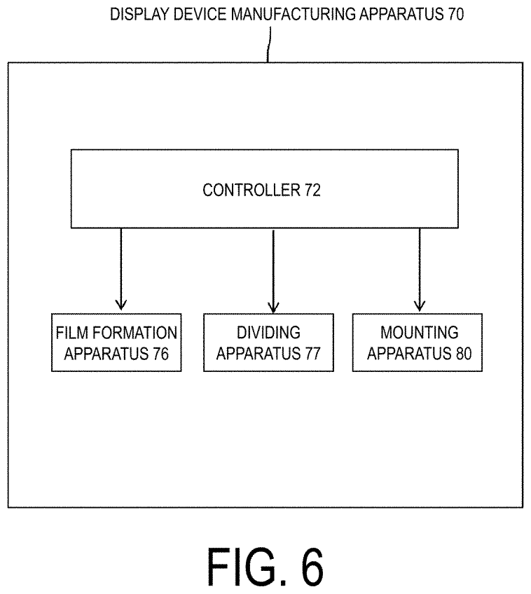

FIG. 6 is a block diagram illustrating a configuration of a display device manufacturing apparatus according to the first embodiment. As illustrated in FIG. 6, a display device manufacturing apparatus 70 includes a film formation apparatus 76, a partitioning apparatus 77, a mounting apparatus 80, and a controller 72 configured to control these apparatuses. The film formation apparatus 76 controlled by the controller 72 performs step S4 in FIG. 1.

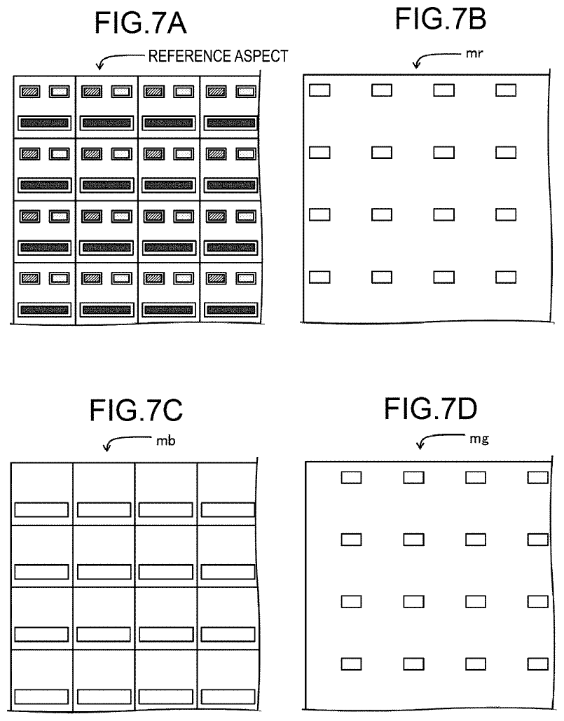

According to the first embodiment, it is easy to perform positioning of the masks because the opening resolution of the masks (Mr, Mb, Mg) used for forming the light-emitting layer of each color may be halved compared to a reference aspect, illustrated in FIG. 7, in which an independent light-emitting layer is formed for each subpixel by using masks (mr, mb, mg) each having the same opening resolution as the resolution of the subpixel of each color. In addition, since a mask like a known stripe type mask is not used, the above-discussed configuration also contributes to achieving a high resolution and a large size.

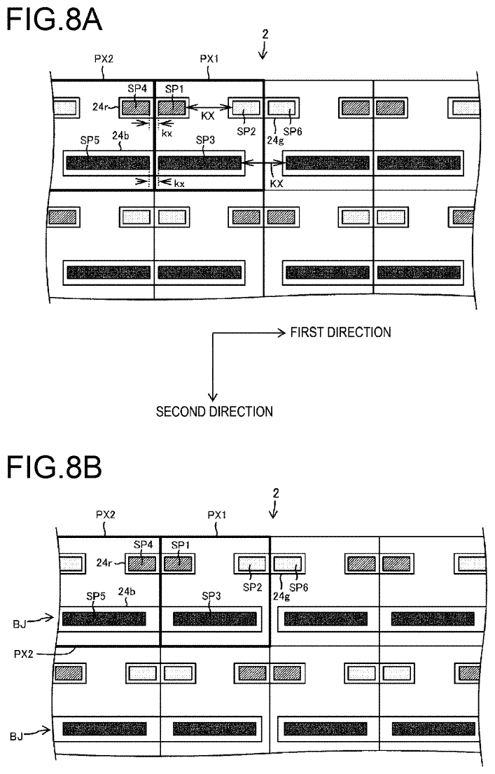

FIG. 8 is a plan view illustrating modification examples of subpixel arrangement according to the first embodiment. As illustrated in FIG. 8(a), a gap width kx between two subpixels being adjacent in the first direction and sharing a light-emitting layer may also be made smaller than a gap width KX between two subpixels being adjacent in the first direction but not sharing a light-emitting layer. For example, the gap width kx between the first subpixel SP1 and fourth subpixel SP4 and the gap width kx between the third subpixel SP3 and fifth subpixel SP5 are made smaller than the gap width KX between the first subpixel SP1 and second subpixel SP2. In this manner, since the light-emitting layer (shared by two subpixels) may be made smaller without changing the size of the light emitting region of each subpixel, the above-discussed configuration is suitable for achieving a high resolution. In addition, since the opening of each color mask is reduced, the strength of the mask is enhanced and the generation of wrinkles or the like is suppressed. This makes it easier to perform positioning of the mask.

However, in FIG. 8(a), since subpixels of the same color adjacent in the first direction are close to each other, there is a possibility that the resolution in the first direction looks low. Because of this, it is desirable to provide a partition for each pixel and a structure in which light of three colors diffuses within the same pixel in order that the adjacent subpixels of the same color are split and recognized visually.

As illustrated in FIG. 8(b), in consideration of the white balance, it is also possible in a blue subpixel row BJ that a gap width between two subpixels being adjacent in the first direction and sharing a light-emitting layer is made equal to a gap width between two subpixels being adjacent in the first direction but not sharing a light-emitting layer in order that the position of the brightness centroid of a pixel unit does not vary in each pixel.

### Second Embodiment

FIG. 9 is a plan view illustrating subpixel arrangement according to a second embodiment. As illustrated in FIG. 9, a display device 2 includes a plurality of pixels PX arranged in a first direction (lateral direction in the drawing) and a second direction (longitudinal direction in the drawing). The pixel PX is configured by a red subpixel SP(R), a blue subpixel SP(B), and a green subpixel SP(G); the subpixel SP(R) and subpixel SP(G) are adjacent to each other in the first direction, and the subpixel SP(B) having a shape extended in the first direction is adjacent to each of the red subpixel SP(R) and the subpixel SP(G) in the second direction; in this manner, each subpixel constitutes an OLED.

In the display device 2 according to the second embodiment, the first direction is a row direction, and the second direction is a column direction; n is an integer equal to or greater than 0; in the (8n+1)th, (8n+4)th, (8n+5)th, and (8n+8)th subpixel rows, a red subpixel pair formed of two red subpixels adjacent in the first direction and a green subpixel pair formed of two green subpixels adjacent in the first direction are alternately arranged; in the (8n+2)th, (8n+3)th, (8n+6)th, and (8n+7)th subpixel rows, a blue subpixel pair formed of two blue subpixels adjacent in the first direction is arranged side by side. In each pair, the two subpixels adjacent in the first direction share a light-emitting layer. When viewed in the second direction, alignment of a red subpixel, blue subpixel, blue subpixel, green subpixel, green subpixel, blue subpixel, blue subpixel, and red subpixel, or alignment of a green subpixel, blue subpixel, blue subpixel, red subpixel, red subpixel, blue subpixel, blue subpixel, and green subpixel is repeated.

The display device 2 according to the second embodiment includes, in addition to the first subpixel SP1 to sixth subpixel SP6 described above, a seventh subpixel SP7 (red) and an eighth subpixel SP8 (red) adjacent to each other in the first direction, a ninth subpixel SP9 (blue) and a tenth subpixel SP10 (blue) adjacent to each other in the first direction, and an eleventh subpixel SP11 (green) and a twelfth subpixel SP12 (green) adjacent to each other in the first direction.

The pixel PX4 is adjacent to each of the pixels PX5 and the pixel PX6 in the first direction, the pixel PX7 and the pixel PX8 are adjacent to each other in the first direction; one of the two pixels adjacent to the pixel PX1 in the second direction (PX4) includes the seventh subpixel SP7 and the eleventh subpixel SP11, and the other one thereof (PX7) includes the ninth subpixel SP9. One of the two pixels adjacent to the pixel PX2 in the second direction (PX5) includes the eighth subpixel SP8, and the other one thereof (PX8) includes the tenth subpixel SP10. The pixel PX6 adjacent to the pixel PX3 in the second direction includes the twelfth subpixel SP12.

In FIG. 9, as for two pixels adjacent in the first direction (for example, PX1 and PX2), the arrangement of three subpixels (red, blue, green) in the respective pixels is line-symmetric while taking a boundary line extending in the second direction between subpixels on both sides as the axis of symmetry; as for two pixels adjacent in the second direction (for example, PX1 and PX4), the arrangement of three subpixels (red, blue, green) in the respective pixels is line-symmetric while taking a boundary line extending in the first direction between subpixels on both sides as the axis of symmetry.

The first subpixel SP1, the fourth subpixel SP4, the seventh subpixel SP7 adjacent to the first subpixel SP1 in the second direction, and the eighth subpixel SP8 adjacent to the fourth subpixel SP4 in the second direction share an island-shaped light-emitting layer 24r. The light-emitting layer 24r is formed to straddle banks separating the subpixels SP1, SP4, SP7, and SP8.

The third subpixel SP3, the fifth subpixel SP5, the ninth subpixel SP9 adjacent to the third subpixel SP3 in the second direction, and the tenth subpixel SP10 adjacent to the fifth subpixel SP5 in the second direction share an island-shaped light-emitting layer 24b. The second subpixel SP2, the sixth subpixel SP6, the eleventh subpixel SP11 adjacent to the second subpixel SP2 in the second direction, and the twelfth subpixel SP12 adjacent to the sixth subpixel SP6 in the second direction share an island-shaped light-emitting layer 24g.

According to the second embodiment, it is easier to perform the positioning of masks because the opening resolution of the masks used for forming the light-emitting layer of each color may be quartered compared to the reference aspect, illustrated in FIG. 7, in which an independent light-emitting layer is formed for each subpixel by using the masks (mr, mb, mg) each having the same opening resolution as the resolution of the subpixel of each color.

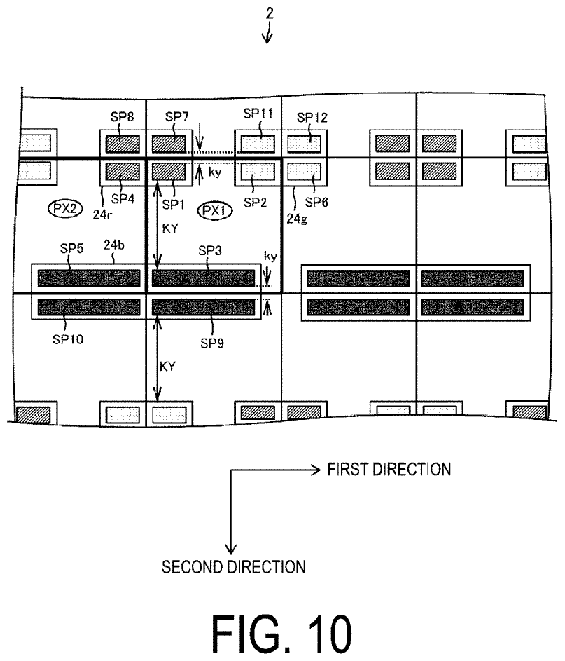

FIG. 10 is a plan view illustrating a modification example of the subpixel arrangement according to the second embodiment. As illustrated in FIG. 10, a gap width between two subpixels being adjacent in the first direction and sharing a light-emitting layer may be made smaller than a gap width between two subpixels being adjacent in the first direction but not sharing a light-emitting layer, and a gap width ky between two subpixels being adjacent in the second direction and sharing a light-emitting layer may be made smaller than a gap width KY between two subpixels being adjacent in the second direction but not sharing a light-emitting layer. For example, the gap width ky between a first subpixel SP1 and a seventh subpixel SP7, and the gap width ky between a third subpixel SP3 and a ninth subpixel SP9 are made smaller than the gap width KY between the first subpixel SP1 and the third subpixel SP3. In this manner, since the light-emitting layer (shared by two subpixels) may be made smaller without changing the size of the light emitting region of each subpixel, the above-discussed configuration is suitable for achieving a high resolution. In addition, since the opening of each color mask is reduced, the strength of the mask is enhanced and the generation of wrinkles or the like is suppressed. This makes it easier to perform positioning of the mask.

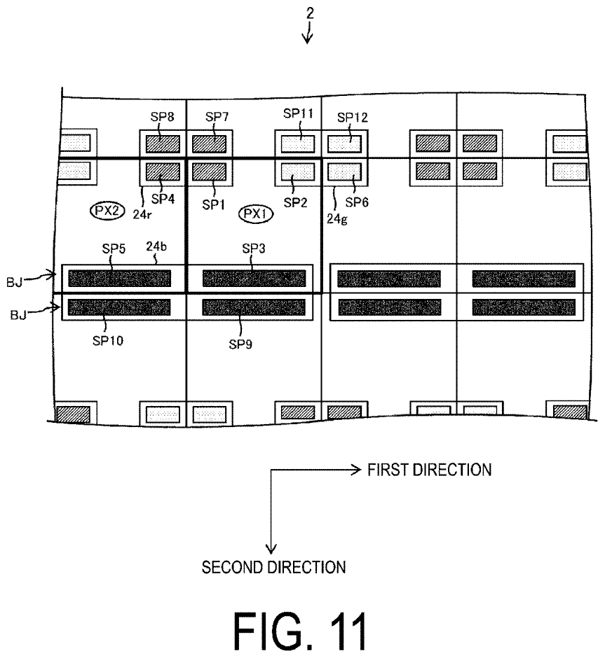

As illustrated in FIG. 11, in consideration of the white balance, it is also possible in a blue subpixel row BJ that a gap width between two subpixels being adjacent in the first direction and sharing a light-emitting layer is made equal to a gap width between two subpixels being adjacent in the first direction but not sharing a light-emitting layer in order that the position of the brightness centroid of a pixel unit does not vary in each pixel.

### First Aspect

A display device includes a first subpixel, a second subpixel, a third subpixel, a fourth subpixel, and a fifth subpixel. The first subpixel and the fourth subpixel adjacent to each other in a first direction share an island-shaped light-emitting layer configured to emit light of a first color, the third subpixel and the fifth subpixel adjacent to each other in the first direction share an island-shaped light-emitting layer configured to emit light of a second color, and the first subpixel and the third subpixel are adjacent to each other in a second direction orthogonal to the first direction.

### Second Aspect

The display device according to the first aspect, for example, further includes a sixth subpixel adjacent to the second subpixel in the first direction. The second subpixel and the sixth subpixel share an island-shaped light-emitting layer configured to emit light of a third color.

### Third Aspect

In the display device according to the second aspect, for example, each of the first subpixel to the sixth subpixel includes a first electrode that is electrically independent.

### Fourth Aspect

In the display device according to the third aspect, for example, the first subpixel and the second subpixel are adjacent to each other in the first direction, and a first pixel is configured by the first subpixel, the second subpixel, and the third subpixel. The fourth subpixel and the fifth subpixel adjacent to each other in the second direction are included in a second pixel adjacent to the first pixel in the first direction.

### Fifth Aspect

In the display device according to the fourth aspect, for example, a gap width between the first subpixel and the fourth subpixel is smaller than a gap width between the first subpixel and the second subpixel.

### Sixth Aspect

In the display device according to the fourth aspect, for example, a gap width between the third subpixel and the fifth subpixel is smaller than a gap width between the first subpixel and the second subpixel.

### Seventh Aspect

In the display device according to the fourth aspect, for example, the first subpixel, the second subpixel, the third subpixel, the fourth subpixel, the fifth subpixel, and the sixth subpixel include a common second electrode.

### Eighth Aspect

In the display device according to the first aspect, for example, the island-shaped light-emitting layer configured to emit the light of the first color is formed straddling a bank between the first subpixel and the fourth subpixel, and the island-shaped light-emitting layer configured to emit the light of the second color is formed straddling a bank between the third subpixel and the fifth subpixel.

### Ninth Aspect

In the display device according to the second aspect, for example, an island-shaped light-emitting layer shared by a plurality of subpixels is formed to straddle a bank separating the plurality of subpixels.

### Tenth Aspect

In the display device according to the fourth aspect, for example, one of the first color and the third color is red and the other one is green, and the second color is blue.

### Eleventh Aspect

In the display device according to the tenth aspect, for example, the third subpixel has a larger light emitting region than the first subpixel and the second subpixel.

### Twelfth Aspect

In the display device according to the eleventh aspect, for example, the third subpixel is larger in size of the light emitting region in the first direction than the first subpixel and the second subpixel.

### Thirteenth Aspect

The display device according to the fourth aspect, for example, further includes a seventh subpixel and an eighth subpixel adjacent to each other in the first direction, and the first subpixel, the fourth subpixel, the seventh subpixel adjacent to the first subpixel in the second direction, and the eighth subpixel adjacent to the fourth subpixel in the second direction share an island-shaped light-emitting layer configured to emit the light of the first color.

### Fourteenth Aspect

The display device according to the thirteenth aspect, for example, further includes a ninth subpixel and a tenth subpixel adjacent to each other in the first direction, and an eleventh subpixel and a twelfth subpixel adjacent to each other in the first direction. The third subpixel, the fifth subpixel, the ninth subpixel adjacent to the third subpixel in the second direction, and the tenth subpixel adjacent to the fifth subpixel in the second direction share an island-shaped light-emitting layer configured to emit the light of the second color. The second subpixel, the sixth subpixel, the eleventh subpixel adjacent to the second subpixel in the second direction, and the twelfth subpixel adjacent to the sixth subpixel in the second direction share an island-shaped light-emitting layer configured to emit the light of the third color.

### Fifteenth Aspect

In the display device according to the fourteenth aspect, for example, one of two pixels adjacent to the first pixel in the second direction includes the seventh subpixel and the eleventh subpixel, and the other one includes the ninth subpixel; one of two pixels adjacent to the second pixel in the second direction includes the eighth subpixel, and the other one includes the tenth subpixel.

### Sixteenth Aspect

In the display device according to the fifteenth aspect, for example, a gap width between the first subpixel and the seventh subpixel is smaller than a gap width between the first subpixel and the third subpixel.

### Seventeenth Aspect

A seventeenth aspect is a manufacturing method for a display device provided with a first subpixel, a second subpixel, a third subpixel, a fourth subpixel, and a fifth subpixel while the first subpixel and the fourth subpixel being adjacent to each other in a first direction, the third subpixel and the fifth subpixel being adjacent to each other in the first direction, and the first subpixel and the third subpixel being adjacent to each other in a second direction orthogonal to the first direction, the method including: first processing in which formed is an island-shaped light-emitting layer configured to emit light of a first color and shared by the first subpixel and the fourth subpixel; and second processing in which formed is an island-shaped light-emitting layer configured to emit light of a second color and shared by the third subpixel and the fifth subpixel.

### Eighteenth Aspect

In the manufacturing method for the display device according to the seventeenth aspect, for example, a resolution of an opening of a first mask used in the first processing is lower than a resolution of a subpixel of the first color, and a resolution of an opening of a second mask used in the second processing is lower than a resolution of a subpixel of the second color.

### Nineteenth Aspect

In the manufacturing method for the display device according to the eighteenth aspect, for example, the resolutions of the first mask and the second mask are the same.

### Twentieth Aspect

In the manufacturing method for the display device according to the eighteenth or nineteenth aspect, for example, the first color is red or green, and the second color is blue.

### Twenty-First Aspect

In the manufacturing method for the display device according to the twentieth aspect, for example, the opening of the second mask is larger than the opening of the first mask.

### Twenty-Second Aspect

A twenty-second aspect is a manufacturing apparatus for a display device provided with a first subpixel, a second subpixel, a third subpixel, a fourth subpixel, and a fifth subpixel while the first subpixel and the fourth subpixel being adjacent to each other in a first direction, the third subpixel and the fifth subpixel being adjacent to each other in the first direction, and the first subpixel and the third subpixel being adjacent to each other in a second direction orthogonal to the first direction. The apparatus includes: performing first processing in which formed is an island-shaped light-emitting layer configured to emit light of a first color and shared by the first subpixel and the fourth subpixel; and performing second processing in which formed is an island-shaped light-emitting layer configured to emit light of a second color and shared by the third subpixel and the fifth subpixel.

### Supplement

An electro-optical element (an electro-optical element whose brightness and transmittance are controlled by a current) that is provided in the display device according to the present embodiments is not particularly limited thereto. Examples of the display device according to the present embodiments include an organic electroluminescence (EL) display provided with the organic light emitting diode (OLED) as the electro-optical element, an inorganic EL display provided with an inorganic light emitting diode as the electro-optical element, and a quantum dot light emitting diode (QLED) display provided with a QLED as the electro-optical element.

### Supplement

The disclosure is not limited to the embodiments stated above. Embodiments obtained by appropriately combining technical approaches disclosed in each of the different embodiments also fall within the scope of the technology of the disclosure. Moreover, novel technical features may be formed by combining the technical approaches disclosed in the embodiments.

### REFERENCE SIGNS LIST

2 Display device
4 TFT layer
5 Light-emitting element layer
6 Sealing layer
10 Lower face film
12 Resin layer
21 Flattening film
24 EL layer
24r, 24g, 24b Light-emitting layer
70 Display device manufacturing apparatus

1. A display device comprising:
a first subpixel;
a second subpixel;
a third subpixel;
a fourth subpixel; and
a fifth subpixel,
wherein the first subpixel and the fourth subpixel adjacent to each other in a first direction share an island-shaped light-emitting layer configured to emit light of a first color,
the third subpixel and the fifth subpixel adjacent to each other in the first direction share an island-shaped light-emitting layer configured to emit light of a second color, and
the first subpixel and the third subpixel are adjacent to each other in a second direction orthogonal to the first direction.

2. The display device according to claim 1, further comprising:
a sixth subpixel adjacent to the second subpixel in the first direction,
wherein the second subpixel and the sixth subpixel share an island-shaped light-emitting layer configured to emit light of a third color.

3. The display device according to claim 2,
wherein each of the first subpixel to the sixth subpixel includes a first electrode that is electrically independent.

4. The display device according to claim 3,
wherein the first subpixel and the second subpixel are adjacent to each other in the first direction, and a first pixel is configured by the first subpixel, the second subpixel, and the third subpixel, and
the fourth subpixel and the fifth subpixel adjacent to each other in the second direction are included in a second pixel adjacent to the first pixel in the first direction.

5. The display device according to claim 4,
wherein a gap width between the first subpixel and the fourth subpixel is smaller than a gap width between the first subpixel and the second subpixel.

6. The display device according to claim 4,
wherein a gap width between the third subpixel and the fifth subpixel is smaller than a gap width between the first subpixel and the second subpixel.

7. The display device according to claim 4,
wherein the first subpixel, the second subpixel, the third subpixel, the fourth subpixel, the fifth subpixel, and the sixth subpixel include a common second electrode.

8. The display device according to claim 1,
wherein the island-shaped light-emitting layer configured to emit the light of the first color is formed straddling a bank between the first subpixel and the fourth subpixel, and
the island-shaped light-emitting layer configured to emit the light of the second color is formed straddling a bank between the third subpixel and the fifth subpixel.

9. The display device according to claim 2,
wherein an island-shaped light-emitting layer shared by a plurality of subpixels is formed to straddle a bank separating the plurality of subpixels.

10. (canceled)

11. The display device according to claim 4,
wherein the third subpixel has a larger light emitting region than the first subpixel and the second subpixel.

12. The display device according to claim 11,
wherein the third subpixel is larger in size of the light emitting region in the first direction than the first subpixel and the second subpixel.

13. The display device according to claim 4, further comprising:
a seventh subpixel and an eighth subpixel adjacent to each other in the first direction,
wherein the first subpixel, the fourth subpixel, the seventh subpixel adjacent to the first subpixel in the second direction, and the eighth subpixel adjacent to the fourth subpixel in the second direction share an island-shaped light-emitting layer configured to emit the light of the first color.

14. The display device according to claim 13, further comprising:
a ninth subpixel and a tenth subpixel adjacent to each other in the first direction; and
an eleventh subpixel and a twelfth subpixel adjacent to each other in the first direction,
wherein the third subpixel, the fifth subpixel, the ninth subpixel adjacent to the third subpixel in the second direction, and the tenth subpixel adjacent to the fifth subpixel in the second direction share an island-shaped light-emitting layer configured to emit the light of the second color, and
the second subpixel, the sixth subpixel, the eleventh subpixel adjacent to the second subpixel in the second direction, and the twelfth subpixel adjacent to the sixth subpixel in the second direction share an island-shaped light-emitting layer configured to emit the light of the third color.

15. The display device according to claim 14,
wherein one of two pixels adjacent to the first pixel in the second direction includes the seventh subpixel and the eleventh subpixel, and the other one includes the ninth subpixel, and
one of two pixels adjacent to the second pixel in the second direction includes the eighth subpixel, and the other one includes the tenth subpixel.

16. The display device according to claim 15,
wherein a gap width between the first subpixel and the seventh subpixel is smaller than a gap width between the first subpixel and the third subpixel.

17. A manufacturing method for a display device provided with a first subpixel, a second subpixel, a third subpixel, a fourth subpixel, and a fifth subpixel while the first subpixel and the fourth subpixel being adjacent to each other in a first direction, the third subpixel and the fifth subpixel being adjacent to each other in the first direction, and the first subpixel and the third subpixel being adjacent to each other in a second direction orthogonal to the first direction, the method comprising:
a first processing in which formed is an island-shaped light-emitting layer configured to emit light of a first color and shared by the first subpixel and the fourth subpixel; and
a second processing in which formed is an island-shaped light-emitting layer configured to emit light of a second color and shared by the third subpixel and the fifth subpixel.

18. The manufacturing method for the display device according to claim 17,
wherein a resolution of an opening of a first mask used in the first processing is lower than a resolution of a subpixel of the first color, and
a resolution of an opening of a second mask used in the second processing is lower than a resolution of a subpixel of the second color.

19. The manufacturing method for the display device according to claim 18,
wherein the resolutions of the first mask and the second mask are the same.

20. (canceled)

21. The manufacturing method for the display device according to claim 18,
wherein the opening of the second mask is larger than the opening of the first mask.

22. A manufacturing apparatus for a display device provided with a first subpixel, a second subpixel, a third subpixel, a fourth subpixel, and a fifth subpixel while the first subpixel and the fourth subpixel being adjacent to each other in a first direction, the third subpixel and the fifth subpixel being adjacent to each other in the first direction, and the first subpixel and the third subpixel being adjacent to each other in a second direction orthogonal to the first direction, the apparatus comprising:
performing a first processing in which formed is an island-shaped light-emitting layer configured to emit light of a first color and shared by the first subpixel and the fourth subpixel; and
performing a second processing in which formed is an island-shaped light-emitting layer configured to emit light of a second color and shared by the third subpixel and the fifth subpixel.
